(19) United States
(12) Patent Application Publication
(10) Pub. No.: US 2025/0294725 A1
(43) Pub. Date: Sep. 18, 2025

(54) SEMICONDUCTOR DEVICES HAVING MOLD STRUCTURE

(71) Applicant: Samsung Electronics Co., Ltd., Suwon-si (KR)

(72) Inventors: Jaewon Na, Suwon-si (KR); Julpin Park, Suwon-si (KR); Hana Cho, Suwon-si (KR)

(21) Appl. No.: 18/960,020

(22) Filed: Nov. 26, 2024

(30) Foreign Application Priority Data
Mar. 12, 2024 (KR) 10-2024-0034330

(51) Int. Cl. H10B 12/00

(52) U.S. Cl. CPC H10B 12/482; H10B 12/315; H10B 12/488

(57) ABSTRACT

A semiconductor device includes a bit line; a molded structure on the bit line, the molded structure including a metal-containing layer; a channel structure on a side surface of the molded structure, the channel structure having a horizontal portion on the bit line and a vertical channel portion extending upwardly, the vertical channel portion on a side surface of the metal-containing layer; a word line on the horizontal portion, the word line overlapping the bit line; and a landing pad on the vertical channel portion and electrically connected to the channel structure, wherein the molded structure further includes a first oxide layer between the metal-containing layer and the vertical channel portion, the vertical channel portion includes: an upper portion contacting the landing pad; a lower portion connected to the horizontal portion; and an intermediate portion between the upper and lower portions, the intermediate portion contacting the first oxide layer.

### CROSS-REFERENCE TO RELATED APPLICATIONS

This application claims benefit of priority to Korean Patent Application No. 10-2024-0034330 filed on Mar. 12, 2024 in the Korean Intellectual Property Office, the disclosure of which is incorporated herein by reference in its entirety.

### BACKGROUND OF THE INVENTION

The present inventive concept relates to semiconductor devices having a molded structure.

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it may be necessary to implement patterns having a fine width or a fine isolation distance.

### SUMMARY OF THE INVENTION

An aspect of the present inventive concept may provide a semiconductor device having a molded structure including a metal-containing layer and an oxide layer.

According to an aspect of the present inventive concept, there is provided a semiconductor device including a bit line; a molded structure on the bit line, the molded structure including a metal-containing layer; a channel structure on a side surface of the molded structure, the channel structure having a horizontal portion on the bit line and a vertical channel portion extending upwardly from one end of the horizontal portion, the vertical channel portion having at least a portion on a side surface of the metal-containing layer; a word line on the horizontal portion, the word line overlapping the bit line in a first direction; and a landing pad on the vertical channel portion, the landing pad electrically connected to the channel structure, wherein the molded structure further includes a first oxide layer between the metal-containing layer and the vertical channel portion in a second direction, wherein the vertical channel portion includes: an upper portion in contact with the landing pad; a lower portion connected to the horizontal portion; and an intermediate portion between the upper portion and the lower portion in the first direction, the intermediate portion in contact with the first oxide layer, wherein the first direction is perpendicular to an upper surface of the bit line, and wherein the second direction is parallel with the upper surface of the bit line.

According to another aspect of the present inventive concept, there is provided a semiconductor device including bit lines extending in a first horizontal direction, the bit lines spaced apart from each other in a second horizontal direction that intersects the first horizontal direction; a molded structure extending on the bit lines in the second horizontal direction; a first channel structure and a second channel structure on a side surface of the molded structure, the first channel structure and the second channel structure spaced apart from each other in the second horizontal direction, the first channel structure and the second channel structure respectively having a horizontal portion on the bit lines and a vertical channel portion extending away from the bit lines; a word line on the horizontal portions, the word line extending in the second horizontal direction; a dielectric structure extending between the word line and the first channel structure and between the word line and the second channel structure; and landing pads on the vertical channel portions, wherein the molded structure includes a first metal-containing layer overlapping the first channel structure in the first horizontal direction, and a first oxide layer between the first metal-containing layer and the first channel structure, and wherein the first horizontal direction and the second horizontal direction are parallel with an upper surface of the bit lines.

According to another aspect of the present inventive concept, there is provided a semiconductor device including a lower structure including a circuit device; a bit line on the lower structure; a molded structure on the bit line, the molded structure including a metal-containing layer; a channel structure on a side surface of the molded structure, the channel structure having a horizontal portion on the bit line and a vertical channel portion extending away from the bit line, the vertical channel portion having at least a portion on a side surface of the metal-containing layer; a word line on the horizontal portion, the word line overlapping the bit line in a first direction that is perpendicular to an upper surface of the bit line; an interlayer insulating layer on the bit line and the word line; an upper capping layer on the molded structure and the interlayer insulating layer; a landing pad on the vertical channel portion, the landing pad passing through the upper capping layer in the first direction, the landing pad electrically connected to the channel structure; and an information storage structure on the landing pad, wherein the molded structure includes an oxide layer between the metal-containing layer and the vertical channel portion, wherein the vertical channel portion includes: an upper portion in contact with the landing pad; a lower portion connected to the horizontal portion; and an intermediate portion between the upper portion and the lower portion in the first direction, the intermediate portion in contact with the oxide layer, wherein the metal-containing layer includes a first metal element, wherein the channel structure includes a semiconductor oxide including oxygen, and wherein the oxide layer includes the first metal element and the oxygen from the semiconductor oxide of the channel structure.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view of a semiconductor device according to an example embodiment;

FIG. 1B is a vertical cross-sectional view taken along line I-I′ of the semiconductor device illustrated in FIG. 1A;

FIG. 1C is a vertical cross-sectional view taken along line II-II′ of the semiconductor device illustrated in FIG. 1A;

FIG. 2 is an enlarged view of a portion of the semiconductor device illustrated in FIG. 1A;

FIG. 3 is an enlarged view of a portion of the semiconductor device illustrated in FIG. 1B;

FIGS. 4 to 7 are vertical cross-sectional views of a semiconductor device according to some example embodiments;

FIGS. 8 and 9 are plan views of a semiconductor device according to some example embodiments;

FIG. 10A is a plan view of a semiconductor device according to an example embodiment;

FIG. 10B is a vertical cross-sectional view taken along line III-III′ of the semiconductor device illustrated in FIG. 10A;

FIG. 10C is a cross-sectional view taken along line IV-IV′ of the semiconductor device illustrated in FIG. 10B; and

FIGS. 11A, 11B, 11C, 12A, 12B, 13A, 13B, 13C, 14A, 14B, 14C, 15A, 15B, 15C, 16A, and 16B are plan views and vertical cross-sectional views of sequential processes of a method of manufacturing a semiconductor device according to an example embodiment.

### DETAILED DESCRIPTION

Hereinafter, example embodiments of the present inventive concept will be described with reference to the attached drawings.

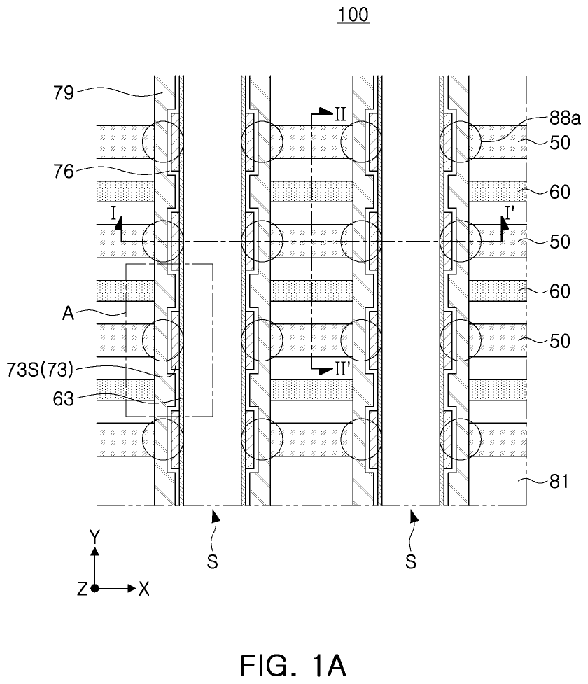

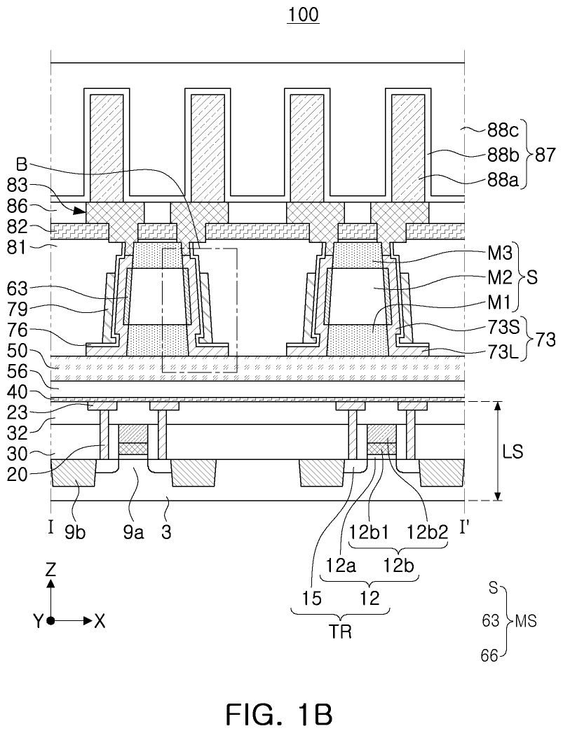

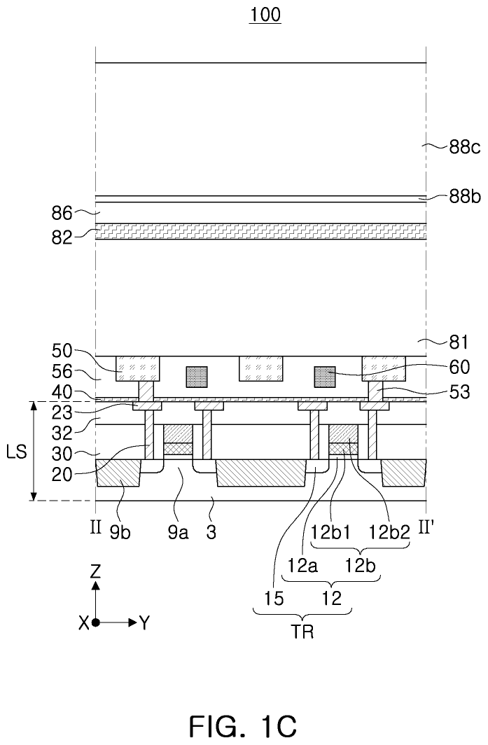

FIG. 1A is a plan view of a semiconductor device according to an example embodiment. FIG. 1B is a vertical cross-sectional view taken along line I-I′ of the semiconductor device illustrated in FIG. 1A. FIG. 1C is a vertical cross-sectional view taken along line II-II′ of the semiconductor device illustrated in FIG. 1A.

Referring to FIGS. 1A, 1B, and 1C, a semiconductor device 100 according to an example embodiment of the present inventive concept may include a lower structure LS, a bit line 50, a molded structure MS, a channel structure 73, and a word line 79, a landing pad 83, and an information storage structure 87. The bit line 50, the channel structure 73, and the word line 79 may be included in a vertical channel transistor of the semiconductor device 100.

The lower structure LS may include a substrate 3, a circuit device TR, a peripheral plug 20, a peripheral interconnection 23, a first peripheral insulating layer 30, and a second peripheral insulating layer 32. The substrate 3 may include a semiconductor material, for example, a group IV semiconductor, a group III-V compound semiconductor, and/or a group II-VI compound semiconductor. For example, the group IV semiconductor may include silicon, germanium, and/or silicon-germanium. The substrate 3 may include a silicon substrate, a silicon on insulator (SOI) substrate, a germanium substrate, a germanium on insulator (GOI) substrate, a silicon-germanium substrate, or a substrate including an epitaxial layer. As used herein, the term “and/or” includes any and all combinations of one or more of the associated listed items.

The circuit device TR may include a word line driver, a sense amplifier, row and column decoders, and/or control circuits. The circuit device TR may include a peripheral transistor. For example, the peripheral transistor may include a gate structure 12, disposed on a peripheral active region 9a defined by a device isolation region 9b in the substrate 3, and peripheral source/drain regions 15 disposed in the peripheral active region 9a on sides of the gate structure 12 opposite to each other (in an X-direction and/or a Y-direction).

The gate structure 12 may include a peripheral gate electrode 12b, and a peripheral gate dielectric layer 12a between the peripheral gate electrode 12b and the peripheral active region 9a of the substrate 3. The peripheral gate electrode 12b may include at least two conductive layers, for example, a first conductive layer 12b1 and a second conductive layer 12b2 on the first conductive layer 12b1.

The peripheral plug 20 may be connected to the peripheral source/drain region 15 and may vertically extend (e.g., in a Z-direction), and the peripheral interconnection 23 may be disposed on the peripheral plug 20. The peripheral interconnection 23 may be electrically connected to the circuit device TR through the peripheral plug 20. The first peripheral insulating layer 30 may be on (e.g., extend around or surround) side surfaces of the peripheral gate electrode 12b and the peripheral plug 20. The second peripheral insulating layer 32 may be disposed on the first peripheral insulating layer 30, and may be on (e.g., extend around or surround) (side surfaces of) the peripheral plug 20 and the peripheral interconnection 23 (and a lower surface of the peripheral interconnection 23). An upper surface of the second peripheral insulating layer 32 may be coplanar with an upper surface of the peripheral interconnection 23. It will be understood that when an element or layer is referred to as being “on”, “responsive to”, “connected to”, or “coupled to” another element or layer, it may be directly on, responsive to, connected to, or coupled to the other element or layer, or one or more intervening elements or layers may be present. In contrast, when an element is referred to as being “directly on”, “directly responsive to”, “directly connected to”, or “directly coupled to”, another element, there are no intervening elements present. In addition, “electrical connection” conceptually includes a physically direct connection and a physically indirect connection. Herein, when an element A is referred to as being “connected to” an element B (or referred to similarly), the elements A and B may be electrically connected to each other unless clearly described otherwise. The X-direction and the Y-direction are parallel with a lower surface (and/or an upper surface) of the bit line 50. The X-direction and the Y-direction intersect with (e.g., are perpendicular to) each other. The Z-direction is perpendicular to the lower surface (or the upper surface) of the bit line 50. The X-direction and the Y-direction may be referred to as horizontal directions, and the Z-direction may be referred to as a vertical direction. For example, the X-direction and the Y-direction may be parallel with a lower surface (and/or an upper surface) of the substrate 3, and the Z-direction may be perpendicular to the lower surface (and/or the upper surface) of the substrate 3.

In an example embodiment, the peripheral plug 20 and the peripheral interconnection 23 may include a metal layer and a barrier layer on (e.g., covering) a side surface and a lower surface of the metal layer. The barrier layer may include, for example, TiN, TaN, WN, TiSiN, TaSiN, and/or RuTiN, and the metal layer may include a metal material such as W or Mo. The first peripheral insulating layer 30 and the second peripheral insulating layer 32 may include, for example, silicon oxide, silicon nitride, silicon oxynitride, a low-κ dielectric, and/or combinations thereof.

The semiconductor device 100 may further include an etch stop layer 40 disposed on the lower structure LS. The etch stop layer 40 may be on (e.g., overlap in the Z-direction or cover) the peripheral interconnection 23 and the second peripheral insulating layer 32. The etch stop layer 40 may include, for example, SiBN, SiCN, SiN, and/or combinations thereof.

The bit line 50 may be disposed on the lower structure LS. The bit lines 50 may extend in the X-direction, and may be spaced apart from each other in the Y-direction. The semiconductor device 100 may further include a bit line plug 53 disposed on a lower portion (e.g., a lower surface) of the bit line 50, and a bit line insulating layer 56 on (extending around or surrounding) the bit line 50 and the bit line plug 53. For example, the bit line insulating layer 56 may be on the etch stop layer 40, and the bit line 50 may be in the bit line insulating layer 56. The bit line plug 53 may extend in the bit line insulating layer 56 and the etch stop layer 40 to be connected (e.g., electrically connected) to the peripheral interconnection 23. The bit line 50 may be electrically connected to the lower structure LS through the bit line plug 53.

The bit line 50 may include a metal layer and a barrier layer on (e.g., covering) a side surface and a lower surface of the metal layer. The barrier layer may include, for example, TiN, TaN, WN, TiSiN, TaSiN, and/or RuTiN, and the metal layer may include a metal material such as W or Mo. The bit line plug 53 may include a material the same as those of the peripheral plug 20 and the peripheral interconnection 23. The bit line insulating layer 56 may include, for example, silicon oxide, silicon nitride, silicon oxynitride, a low-κ dielectric, and/or combinations thereof. A low-κ dielectric (material) may refer to a material having a lower dielectric constant than that of silicon oxide.

The semiconductor device 100 may further include shielding patterns 60 extending in the X-direction, the shielding patterns 60 spaced apart from each other in the Y-direction. The shielding patterns 60 may be disposed alternately with the bit lines 50 in the Y-direction. A lower surface of the shielding pattern 60 may be positioned on a level, lower than that of a lower surface of the bit line 50, and an upper surface of the shielding pattern 60 may be positioned on a level, lower than that of an upper surface of the bit line 50. The shielding patterns 60 may reduce capacitance between bit lines 50. Herein, the level may be a relative location (e.g., distance) from the lower surface of the substrate 3 in the Z-direction. A farther distance from the lower surface of the substrate 3 may be a higher level. A closer distance from the lower surface of the substrate 3 may be a lower level.

The shielding pattern 60 may include, for example, doped polysilicon, a metal, a conductive metal nitride, a metal-semiconductor compound, a metal compound, a conductive metal oxide, graphene, carbon nanotubes, and/or combinations thereof.

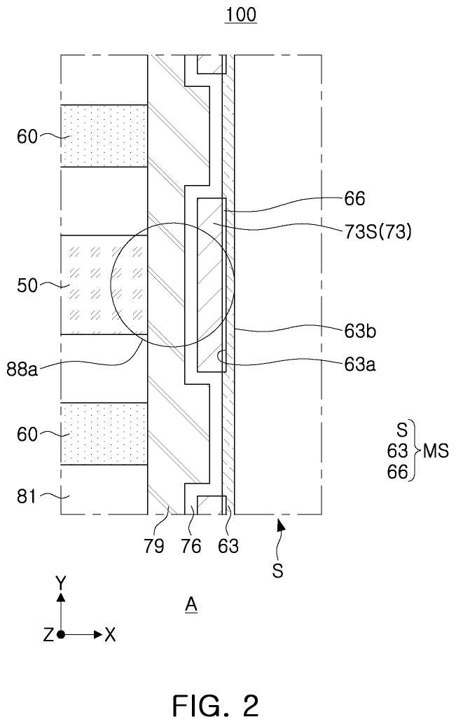

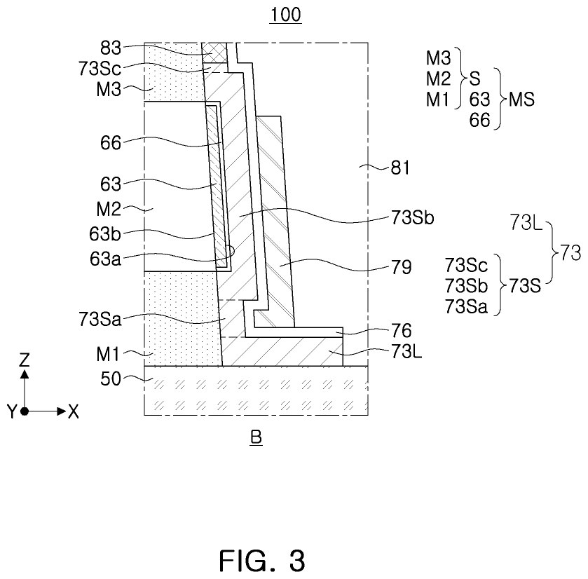

FIG. 2 is an enlarged view of a portion of the semiconductor device illustrated in FIG. 1A. FIG. 2 may correspond to region A of FIG. 1A. FIG. 3 is an enlarged view of a portion of the semiconductor device illustrated in FIG. 1B. FIG. 3 may correspond to region B of FIG. 1B.

Referring further to FIGS. 2 and 3, the molded structure MS may be disposed on the bit line 50. In plan view, the molded structures MS may extend in the Y-direction, and may be spaced apart from each other in the X-direction. The molded structure MS may include a mold stack S, a metal-containing layer 63, and an oxide layer 66.

The mold stack S may extend in the Y-direction. In an example embodiment, the mold stack S may include a first molded layer M1, a second molded layer M2, and a third molded layer M3, sequentially stacked. The first molded layer M1, the second molded layer M2, and the third molded layer M3 may include, for example, silicon oxide, silicon nitride, silicon oxynitride, and/or combinations thereof. In an example embodiment, the second molded layer M2 may include a material, different from those of the first molded layer M1 and the third molded layer M3. For example, the second molded layer M2 may include silicon oxide, and the first molded layer M1 and the third molded layer M3 may include silicon nitride. The horizontal width of the mold stack S (in the X-direction and/or Y-direction) may downwardly increase. For example, in a cross-sectional view, the mold stack S may have a trapezoidal shape. However, the structure and the material of the mold stack S describe above are examples, and are not limited thereto.

In an example embodiment, the metal-containing layer 63 may be disposed on a side surface of the mold stack S. The metal-containing layers 63 may be disposed on side surfaces of the mold stack S opposite to each other in the X-direction. For example, the metal-containing layers 63 may be spaced apart from each other in the X-direction with the mold stack S interposed therebetween, and may extend in the Y-direction along the mold stack S. The metal-containing layer 63 may include a first side surface 63a facing the channel structure 73, and a second side surface 63b opposite to the first side surface 63a, the second side surface 63b in contact with the side surface of the mold stack S. In an example embodiment, the second side surface 63b of the metal-containing layer 63 may be in contact with (a side surface of) the second molded layer M2 of the mold stack S, but the present inventive concept is not limited thereto. In some example embodiments, the second side surface 63b of the metal-containing layer 63 may also be in contact with (a side surface of) the first molded layer M1 and (a side surface of) the third molded layer M3 of the mold stack S.

The metal-containing layer 63 may include, for example, a metal, a conductive metal nitride, a metal-semiconductor compound, and/or a conductive metal oxide. For example, the metal-containing layer 63 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, and/or RuOₓ, but the present inventive concept is not limited thereto. The metal-containing layer 63 may include a single layer or multiple layers, including (e.g., formed of) the above-described materials. In an example embodiment, the metal-containing layer 63 may include a semiconductor oxide such as indium gallium zinc oxide (IGZO), tungsten dope indium oxide (IWO), indium gallium tin oxide (IGTO), and indium aluminum zinc oxide (IAZO).

The oxide layer 66 may be disposed between the metal-containing layer 63 and a vertical channel portion 73S of the channel structure 73. For example, the oxide layer 66 may be on (e.g., cover) an upper surface, a lower surface, and a first side surface 63a of the metal-containing layer 63. In some example embodiments, the oxide layer 66 may also be on (e.g., cover) a second side surface 63b of the metal-containing layer 63. In some embodiments, in a plan view, the first side surface 63a may face the channel structure 73 (e.g., the vertical channel portion 73S of the channel structure 73) in the X-direction, and the second side surface 63b may face the mold structure S in the X-direction. For example, in a plan view, the first side surface 63a and the second side surface 63b of the metal-containing layer 63 may be opposite to each other in the X-direction. In plan view, the oxide layers 66 may extend in the Y-direction, and may be spaced apart from each other in the Y-direction. In plan view, the first side surface 63a of the metal-containing layer 63 may have recesses recessed in the X-direction, and the oxide layers 66 may fill the recesses. For example, the recesses may overlap with the channel structure 73 in the X-direction in a plan view. A metal element of the metal-containing layer 63 may react (e.g., chemically combined) with an oxygen element of the channel structure 73 to form the oxide layer 66. The metal-containing layer 63 may include a first metal element, the channel structure 73 may include a semiconductor oxide including oxygen, and the oxide layer 66 may include the first metal element and oxygen (from the semiconductor oxide of the channel structure 73).

The metal-containing layer 63 and the oxide layer 66 may not be in contact with (e.g., may be spaced apart from) both the bit line 50 and the landing pad 83. The metal-containing layer 63 and the oxide layer 66 may not be electrically connected to (e.g., may be electrically isolated or insulated from) both the bit line 50 and the landing pad 83, and may be electrically floating.

The channel structure 73 may be disposed on the bit line 50. The channel structure 73 may have a horizontal portion 73L on (in contact with) the bit line 50, the horizontal portion 73L electrically connected to the bit line 50, and a vertical channel portion 73S extending upwardly from one end of the horizontal portion 73L in the X-direction. For example, the vertical channel portion 73S may be on or above the horizontal portion 73L. The vertical channel portion 73S may overlap the horizontal portion 73L in the Z-direction. The vertical channel portion 73S may extend away from the bit line 50. In some embodiments, the vertical channel portion 73S and the horizontal portion 73L may form an integrated unitary structure (e.g., the channel structure 73). Herein, an integrated unitary structure may refer to a structure including sub-elements that are formed of a same material and have no visible boundaries therebetween. A lower surface of the horizontal portion 73L may be in contact with the bit line 50, and the horizontal portion 73L may be electrically connected to the bit line 50. The vertical channel portion 73S may be on (e.g., cover) a side surface of the molded structure MS, and may upwardly extend.

In plan view, the channel structures 73 may be disposed on side surfaces of the oxide layers 66. The oxide layer 66 may be disposed between the channel structure 73 and the metal-containing layer 63, and the channel structure 73 may be spaced apart from the metal-containing layer 63 by the oxide layer 66. The channel structures 73 may be spaced apart from each other in the X-direction and Y-direction. A horizontal width of the channel structure 73 in the Y-direction may be the same as a horizontal width of the oxide layer 66 in the Y-direction, but the present inventive concept is not limited thereto.

In cross-sectional view, (the vertical channel portion 73S of) the channel structure 73 may have a lower portion 73Sa, an intermediate portion 73Sb, and an upper portion 73Sc. The lower portion 73Sa may be on (e.g., in contact with) the first molded layer M1, and may be on (e.g., connected to) the horizontal portion 73L. The upper portion 73Sc may be on (e.g., in contact with) the third molded layer M3, and may be on (e.g., connected to) the landing pad 83. The intermediate portion 73Sb may be disposed between the lower portion 73Sa and the upper portion 73Sc (in the Z-direction), and may be on (e.g., cover) the metal-containing layer 63 and the oxide layer 66. For example, at least a portion of the intermediate portion 73Sb may overlap the metal-containing layer 63 and the oxide layer 66 in the X-direction (and/or the Z-direction). The intermediate portion 73Sb may protrude in a horizontal direction (e.g., in the X-direction) from the lower portion 73Sa and the upper portion 73Sc. In an example embodiment, the lower portion 73Sa and the upper portion 73Sc may correspond to source/drain regions of a vertical channel transistor. In some embodiments, the lower portion 73Sa, the intermediate portion 73Sb, and the upper portion 73Sc may form an integrated unitary structure (e.g., the channel structure 73).

In FIG. 1B, it is illustrated that the channel structures 73 are spaced apart from each other in the X-direction, but the present invention is not limited thereto. In some example embodiments, the horizontal portions 73L of the channel structures 73, adjacent to each other and facing each other in the X-direction, may extend on the bit line 50 in the horizontal direction (e.g., in the X-direction), and thus may be integrally formed (may form an integrated unitary structure).

The channel structure 73 may include (e.g., be formed of) a semiconductor material such as silicon or the like. The channel structure 73 may include (e.g., be formed of) single crystal silicon and/or polysilicon. However, the channel structure 73 is not limited to the semiconductor materials such as silicon or the like, and may include (e.g., be formed of) other semiconductor materials, usable as a channel region of a transistor. For example, the channel structure 73 may include a semiconductor oxide layer and/or a two-dimensional (2D) material layer, usable as a channel region of a transistor.

The semiconductor oxide layer (of the channel structure 73) may be indium gallium zinc oxide (IGZO). However, the example embodiment are not limited thereto. For example, the semiconductor oxide layer (of the channel structure 73) may include indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The 2D material layer (of the channel structure 73) may include, for example, a transition metal dichalcogenide (TMD) material layer, a black phosphorous material layer, and/or a hexagonal boron-nitride (hBN) material layer, which may have semiconductor properties. For example, the 2D material layer (of the channel structure 73) may include, for example, BiOSe, Crl, WSe2, MoS₂, TaS, WS, SnSe, ReS, β-SnTe, MnO, AsS, P (black), InSe, h-BN, GaSe, GaN, SrTiO, MXene, and/or a Janus 2D material, which may form a 2D material.

In plan view, the word lines 79 may intersect (may overlap in the Z-direction) the bit lines 50. For example, the word lines 79 may extend in the Y-direction on (along) side surfaces of the molded structures MS, and may be spaced apart from each other in the X-direction. The word line 79 may be disposed on the channel structure 73. For example, the word line 79 may overlap the horizontal portion 73L of the channel structure 73 in a vertical direction (in the Z-direction). An upper end of the word line 79 may be positioned on level, lower than that of an upper surface of the molded structure MS.

The word line 79 may include, for example, doped polysilicon, a metal, a conductive metal nitride, a metal-semiconductor compound, a conductive metal oxide, conductive graphene, carbon nanotubes, and/or combinations thereof. For example, word line 79 may include (e.g., may be) doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, and/or combinations thereof, but the present inventive concept is not limited thereto. The word line 79 may include a single layer or multiple layers, including (e.g., formed of) the above-described materials.

The semiconductor device 100 may further include dielectric structures 76 between the word lines 79 and the channel structure 73. In plan view, the dielectric structure 76 may be disposed between the word line 79 and the channel structure 73, and between the word line 79 and the metal-containing layer 63. The dielectric structure 76 may be in contact with the word line 79, the channel structure 73, and the metal-containing layer 63. In cross-sectional view, the dielectric structure 76 may be disposed between the word line 79 and the vertical channel portion 73S, and between the word line 79 and the horizontal portion 73L. In an example embodiment, a portion of the dielectric structure 76 may be on (e.g., cover or overlap) an upper surface of the third molded layer M3, but the present inventive concept is not limited thereto.

In an example, each of the dielectric structures 76 may be a tunnel dielectric layer, not including an information storage layer. For example, each of the dielectric structures 76 may include, for example, silicon oxide and/or high-κ dielectric. The high dielectric material may include, for example, metal oxide and/or metal oxynitride. For example, the high-κ dielectric may include (e.g., may be formed of) HfO2, HfSiO, HfSiON, HfTaO, HfTIO, HfZrO, ZrO₂, Al₂O₃, and/or combinations thereof, but the present inventive concept is not limited thereto. Each of the dielectric structures 76 may be formed of a single layer or multiple layers including the above-described materials. A high-κ dielectric (material) may refer to a material having a higher dielectric constant than that of silicon oxide.

In another example, each of the dielectric structures 76 may include an information storage layer and a dielectric layer. For example, each of the dielectric structures 76 may have polarization properties depending on an electric field, and may include a ferroelectric layer that may have remnant polarization caused by a dipole even in the absence of an external electric field. Data may be recorded using such a polarization state in the ferroelectric layer. Accordingly, each of the dielectric structures 76 may include a ferroelectric layer, which may be referred to as an information storage layer. The ferroelectric layer, which may be the information storage layer, may include an Hf-based compound, a Zr-based compound, and/or an Hf-Zr-based compound. For example, the Hf-based compound may be a HfO-based ferroelectric material, the Zr-based compound may include a ZrO-based ferroelectric material, and the Hf-Zr-based compound may include a hafnium zirconium oxide (HZO)-based ferroelectric material. The ferroelectric layer, which may be the information storage layer, may include a ferroelectric material doped with an impurity, for example, C, Si, Mg, Al, Y, N, Ge, Sn, Gd, La, Sc, and/or Sr. For example, the ferroelectric layer, which may be the information storage layer, may be a material obtained by doping HfO₂, ZrO₂, and/or HZrO with C, Si, Mg, Al, Y, N, Ge, Sn, Gd, La, Sc, and/or Sr.

In the dielectric structures 76, the information storage layer is not limited to the above-described material types, and may include a material capable of storing information.

The semiconductor device 100 may further include an interlayer insulating layer 81 and an upper capping layer 82. The interlayer insulating layer 81 may be disposed between the molded structures MS (in the X-direction). The interlayer insulating layer 81 may be on (e.g., may cover) the bit lines 50, the channel structures 73, and the word lines 79. The interlayer insulating layers 81 may extend in the Y-direction, and may be spaced apart from each other in the X-direction. The interlayer insulating layers 81 may be disposed alternately with the molded structures MS in the X-direction. The interlayer insulating layer 81 may include, for example, silicon oxide.

The upper capping layer 82 may be on (e.g., may cover) the molded structure MS and the interlayer insulating layer 81, and may extend in the horizontal direction (in the X-direction and/or the Y-direction). The upper capping layer 82 may be in contact with an upper surface of the interlayer insulating layer 81. The upper capping layer 82 may include, for example, silicon nitride.

The landing pad 83 may be disposed on the channel structure 73 and may pass through the upper capping layer 82 to be in contact with the vertical channel portion 73S (e.g., an upper surface of the upper portion 73Sc) of the channel structure 73. The landing pad 83 may be electrically connected to the bit line 50 through the channel structure 73.

The landing pad 83 may include, for example, a metal and/or a metal nitride. The metal nitride may include, for example, TiN, TaN, WN, TiSiN, TaSiN, and/or RuTiN, and the metal may include a metal material such as W or Mo.

The semiconductor device 100 may further include insulating patterns 86 on the upper capping layer 82. The insulating patterns 86 may be disposed between the landing pads 83. The insulating pattern 86 may separate (e.g., electrically insulate) the landing pads 83 from each other. The insulating pattern 86 may include, for example, silicon oxide, silicon nitride, silicon oxynitride, a low-κ dielectric, and/or combinations thereof. For example, the insulating pattern 86 may include silicon oxide.

Referring back to FIG. 1B, the information storage structure 87 may be disposed on the landing pads 83 and the insulating patterns 86. The information storage structure 87 may include first electrodes 88a electrically connected to the landing pads 83. In some embodiments, the first electrodes 88a may be in contact with the landing pads 83. The information storage structure 87 may further include a second electrode 88c on the first electrodes 88a, and a dielectric layer 88b between the first electrodes 88a and the second electrode 88c.

In an example, the information storage structure 87 may be a capacitor in which a DRAM stores information. For example, the dielectric layer 88b of the information storage structure 87 may be a capacitor dielectric layer of the DRAM, and the dielectric layer 88b may include, for example, a high-κ dielectric, silicon oxide, silicon nitride, silicon oxynitride, and/or combinations thereof.

In another example, the information storage structure 87 may be a structure for storing information on a memory different from the DRAM. For example, the information storage structure 87 may be a capacitor of a ferroelectric memory (FeRAM). For example, the dielectric layer 88b may be a ferroelectric layer capable of recording data using a polarization state. In some embodiments, the dielectric layer 88b may include a lower dielectric layer and a ferroelectric layer on the lower dielectric layer. Here, the lower dielectric layer may include, for example, silicon oxide, silicon oxynitride, silicon nitride, and/or a high-κ dielectric.

In an example embodiment, when the dielectric structures 76 include an information storage layer, the information storage structure 87 may be omitted.

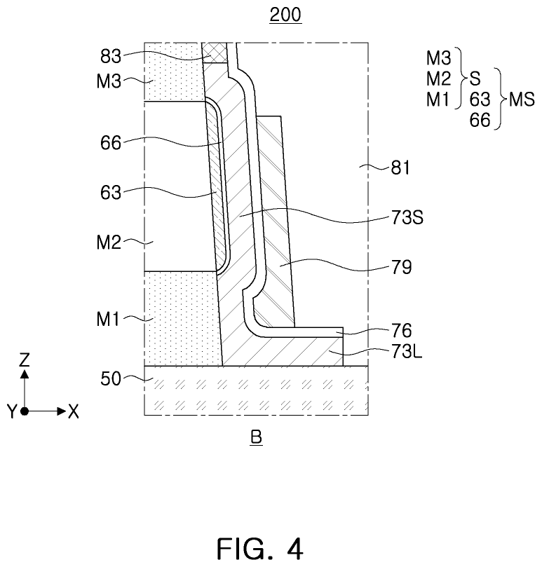

FIGS. 4 to 7 are vertical cross-sectional views of a semiconductor device according to some example embodiments.

Referring to FIG. 4, the molded structure MS of the semiconductor device 200 may include a metal-containing layer 63 and an oxide layer 66, disposed on a side surface of a mold stack S. In an example embodiment, an upper surface and a lower surface of the metal-containing layer 63 may be convex. For example, in a cross-sectional view, an outer side surface of the metal-containing layer 63 may have a gradually inclined (e.g., a gently sloped) shape toward the mold stack S at the upper portion (e.g., the upper end) and the lower portion (e.g., the lower end) of the metal-containing layer 63. For example, a horizontal width (in the X-direction) of an upper portion of the metal-containing layer 63 may upwardly decrease, and a horizontal width (in the X-direction) of a lower portion of the metal-containing layer 63 may downwardly decrease.

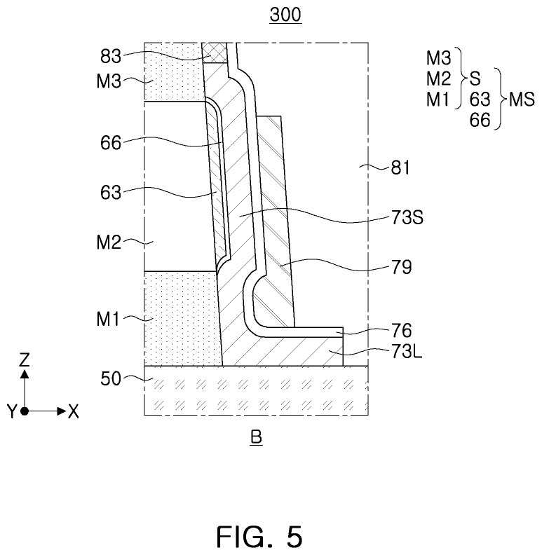

Referring to FIG. 5, a molded structure MS of a semiconductor device 300 may include a metal-containing layer 63 and an oxide layer 66, disposed on a side surface of a mold stack S. In an example embodiment, an upper surface of the metal-containing layer 63 may be convex, and a lower surface of the metal-containing layer 63 may be concave. For example, in a cross-sectional view, an outer side surface of the metal-containing layer 63 may have a gradually inclined (e.g., a gently sloped) shape toward the mold stack S at the upper portion (e.g., the upper end) of the metal-containing layer 63 and an acutely inclined (e.g., an abruptly sloped) shape toward the mold stack S at the lower portion (e.g., the lower end) of the metal-containing layer 63. For example, a horizontal width of an upper portion (in the X-direction) of the metal-containing layer 63 may upwardly decrease, and a horizontal width (in the X-direction) of a lower portion of the metal-containing layer 63 may downwardly decrease.

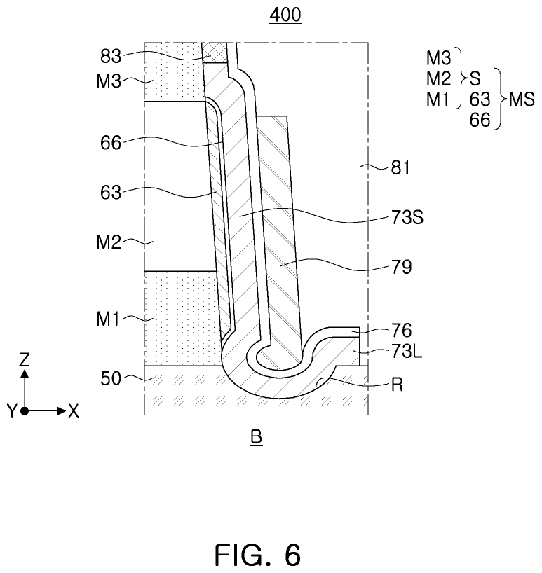

Referring to FIG. 6, a molded structure MS of a semiconductor device 400 may include a metal-containing layer 63 and an oxide layer 66, disposed on a side surface of a mold stack S. In an example embodiment, an upper surface of a bit line 50 may have a recess R, adjacent to the mold stack S. A horizontal portion 73L of a channel structure 73 may be disposed in (e.g., may fill) at least a portion of the recess R. In an example embodiment, at least one of a dielectric structure 76 and a word line 79 may be disposed in (e.g., may fill) at least a portion of the recess R. In some embodiments, the recess R may have a concave shape toward the substrate 3.

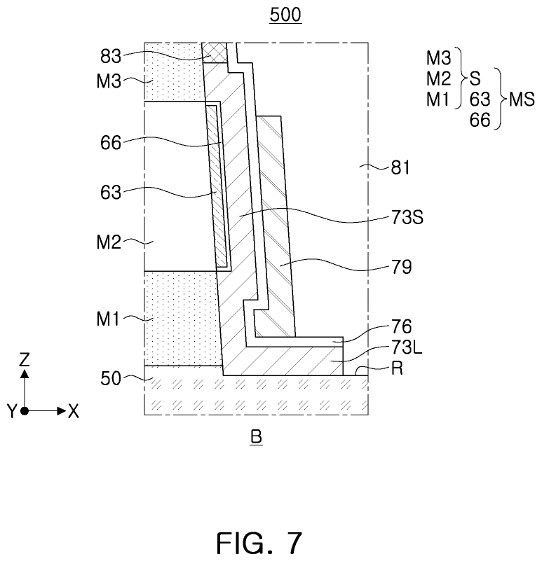

Referring to FIG. 7, a molded structure MS of a semiconductor device 500 may include a metal-containing layer 63 and an oxide layer 66, disposed on a side surface of a mold stack S. In an example embodiment, an upper surface of a bit line 50 may have a recess R. For example, the recess R may be formed between the mold stacks S. A horizontal portion 73L of a channel structure 73 may be disposed in (e.g., may fill) at least a portion of the recess R. For example, the horizontal portion 73L may longitudinally extend in the recess R in the X-direction. In an example embodiment, an interlayer insulating layer 81 may be in contact with an upper surface of the bit line 50 exposed by the recess R. For example, the recess R may form an upper surface of the bit line 50 lower than the uppermost surface of the bit line 50. The interlayer insulating layer 81 may be in contact with the upper surface of the bit line 50 lower than the uppermost surface of the bit line 50. In some embodiments, the upper surface of the bit line 50 lower than the uppermost surface of the bit line 50 may be parallel with the lower surface of the substrate 3.

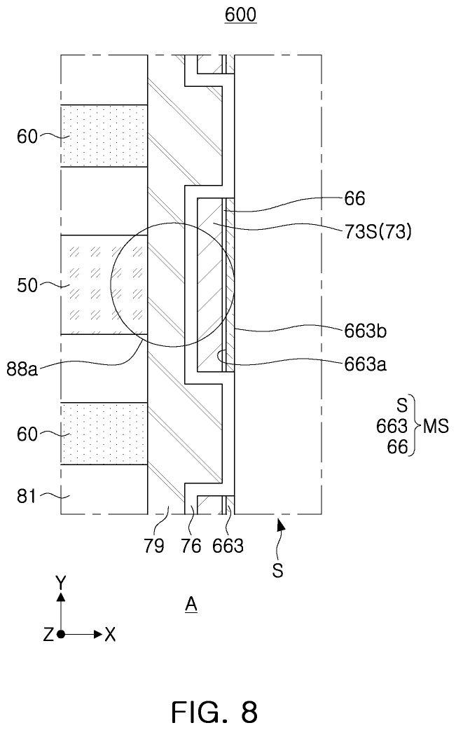

Referring to FIG. 8, a molded structure MS of a semiconductor device 600 may include a metal-containing layer 663 and an oxide layer 66, disposed on a side surface of a mold stack S. In an example embodiment, the metal-containing layers 663 may be spaced apart from each other in a Y-direction along the side surface of the mold stack S. Each of the metal-containing layers 663 may have a first side surface 663a, facing a corresponding channel structure 73 (in the X-direction). Each of the oxide layers 66 may be disposed between a corresponding channel structure 73 and a corresponding metal-containing layer 663, and may be in contact with the first side surface 663a. Each of the metal-containing layers 663 may have a second side surface 663b opposite to the first side surface 663a (in the X-direction), the second side surface 663b in contact with the side surface of the mold stack S.

In an example embodiment, a horizontal width of the channel structure 73 in a Y-direction may be the same as a horizontal width of the metal-containing layer 663 in the Y-direction and the same as a horizontal width of the oxide layer 66 in the Y-direction. In an example embodiment, a dielectric structure 76 may be in contact with the metal-containing layers 663 and the oxide layers 66. A portion of the dielectric structure 76 may be in contact with the side surface of the mold stack S, and may overlap the metal-containing layers 663 and the oxide layers 66 in the Y-direction.

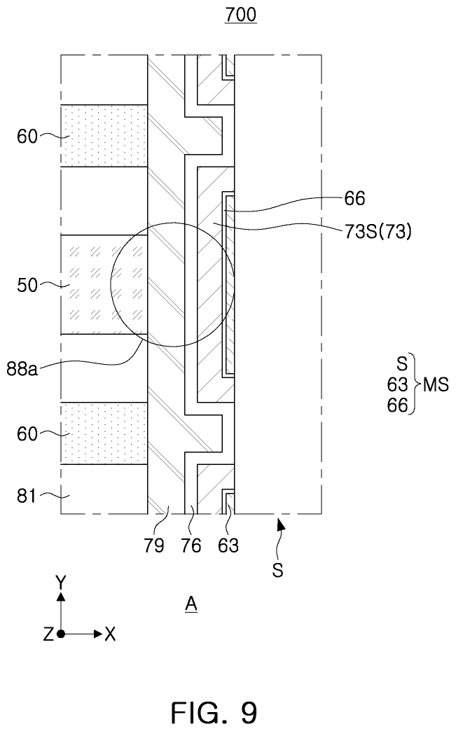

Referring to FIG. 9, a molded structure MS of a semiconductor device 700 may include a metal-containing layer 63 and an oxide layer 66, disposed on a side surface of a mold stack S. In an example embodiment, the metal-containing layers 63 may be spaced apart from each other in the Y-direction along the side surface of the mold stack S. In an example embodiment, a horizontal width of a channel structure 73 in the Y-direction may be wider than a horizontal width of the metal-containing layer 63 in the Y-direction and wider than a horizontal width of the oxide layer 66 in the Y-direction. For example, opposite ends of a vertical channel portion 73S of the channel structure 73 in the Y-direction may extend in the X-direction, and may be in contact with the side surface of the mold stack S. A portion of the vertical channel portion 73S may overlap the metal-containing layers 63 and the oxide layers 66 in the Y-direction. In some embodiments, the horizontal width of the oxide layer 66 in the Y-direction may be wider than the horizontal width of the metal-containing layer 63 in the Y-direction. For example, the oxide layer 66 may overlap the metal-containing layer 63 in the Y-direction. Opposite ends of the oxide layer 66 in the Y-direction may extend in the X-direction, and may be in contact with the side surface of the mold stack S. In a plan view, the oxide layer 66 may extend around at least a portion (e.g., three side surfaces) of the metal-containing layer 63, and the vertical channel portion 73S of the channel structure 73 may extend around at least a portion (e.g., three side surfaces) of the oxide layer 66.

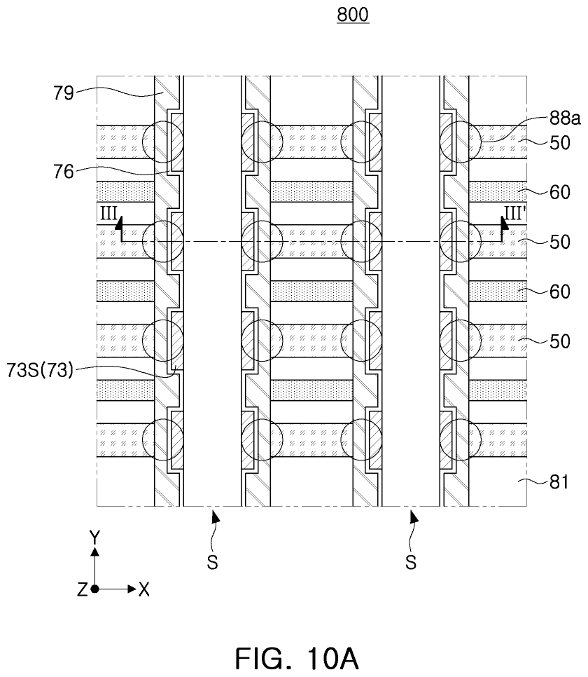

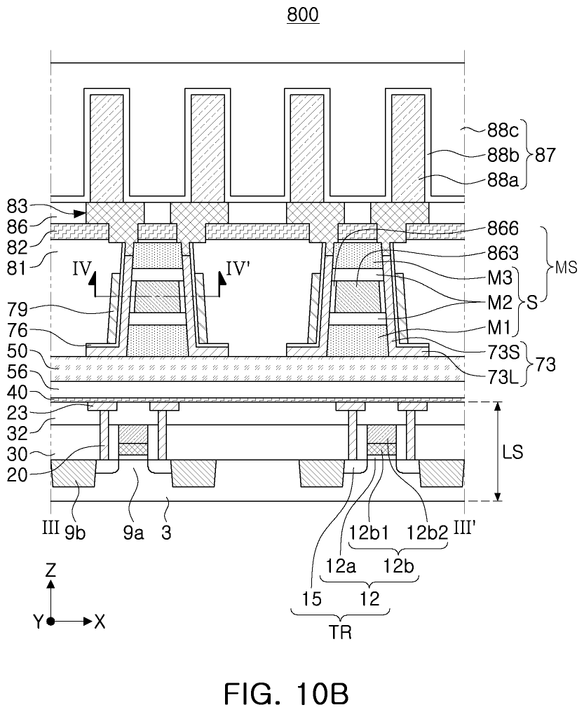

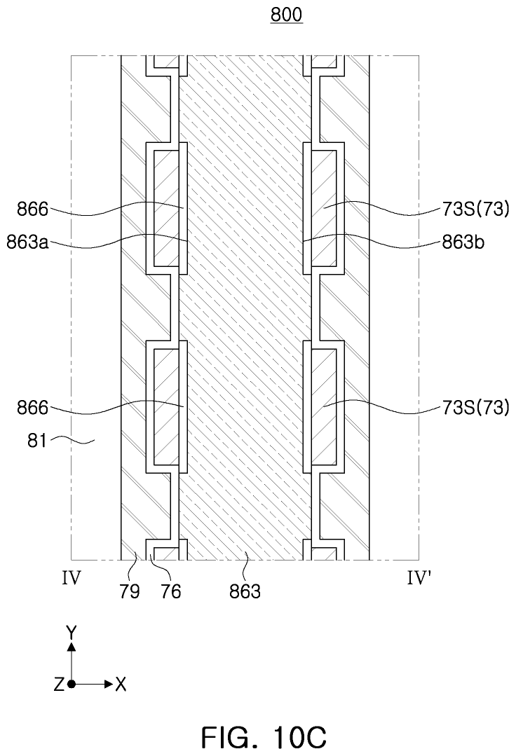

FIG. 10A is a plan view of a semiconductor device according to an example embodiment. FIG. 10B is a vertical cross-sectional view taken along line III-III′ of the semiconductor device illustrated in FIG. 10A. FIG. 10C is a cross-sectional view taken along line IV-IV′ of the semiconductor device illustrated in FIG. 10B.

Referring to FIGS. 10A, 10B, and 10C, a molded structure MS of a semiconductor device 800 may include a metal-containing layer 863, oxide layers 866, and a mold stack S. The metal-containing layer 863 and the oxide layers 866 may be disposed in the mold stack S. For example, the mold stack S may include a first molded layer M1, a second molded layer M2, and a third molded layer M3, sequentially stacked, and the metal-containing layer 863 (and/or the oxide layers 866) may be in (inserted into) the second molded layer M2. In some embodiments, the metal-containing layer 863 and/or the oxide layers 866 may be disposed between the first molded layer M1 and the third molded layer M3 in the Z-direction. For example, in a cross-sectional view, the second molded layer M2 may include portions spaced apart from each other in the Z-direction by the metal-containing layer 863 and/or the oxide layers 866. The metal-containing layer 863 may extend in a Y-direction along the mold stack S. In plan view, the oxide layers 866 may be disposed between channel structures 73 and the metal-containing layer 863 (in the X-direction). For example, the metal-containing layer 863 may include a first side surface 863a and a second side surface 863b opposite to the first side surface 863a (in the X-direction). The first side surface 863a may have first recesses recessed in the X-direction, and the first recesses may be (at least partially) filled with the oxide layers 866. The second side surface 863b may have second recesses recessed in the X-direction, and the second recesses may be (at least partially) filled with the oxide layers 866. In an example embodiment, the metal-containing layer 863 may not have a constant horizontal width (in the X-direction). For example, a horizontal width (in the X-direction) of a portion of the metal-containing layer 863, overlapping the channel structures 73 in the X-direction, may be narrower than a horizontal width (in the X-direction) of a portion of the metal-containing layer 863, not overlapping the channel structures 73 in the X-direction.

The oxide layer 866 (e.g., a side surface of the oxide layer 866) may be coplanar with a side surface of the mold stack S. The oxide layers 866 may be disposed on opposite side surfaces (in the X-direction) of the metal-containing layer 863, and may be spaced apart from each other in the X-direction and the Y-direction. In an example embodiment, a horizontal width of the oxide layers 866 in the Y-direction may be wider than a horizontal width of the channel structures 73 in the Y-direction. The oxide layers 866 may be in contact with dielectric structures 76. The dielectric structures 76 may be in contact with the first side surface 863aand the second side surface 863b of the metal-containing layer 863, respectively.

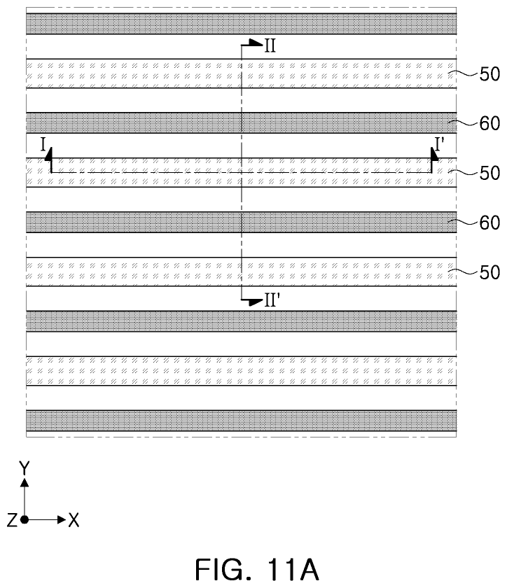

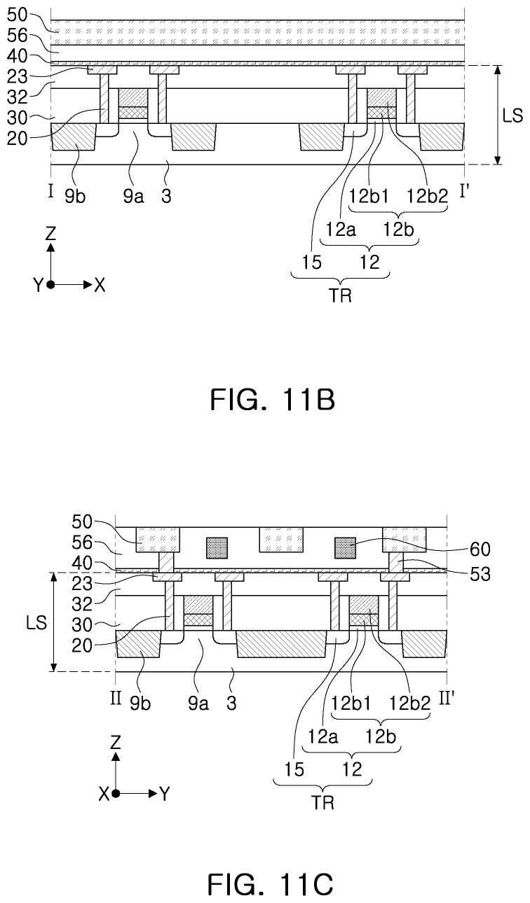

FIGS. 11A, 11B, 11C, 12A, 12B, 13A, 13B, 13C, 14A, 14B, 14C, 15A, 15B, 15C, 16A, and 16B are plan views and vertical cross-sectional views of sequential processes of a method of manufacturing a semiconductor device according to an example embodiment.

Specifically, FIGS. 11A, 12A, 13A, 14A, 15A, and 16A are plan views corresponding to FIG. 1. FIGS. 11B, 12B, 13B, 14B, 15B, and 16B are vertical cross-sectional views corresponding to FIG. 1B. FIGS. 11C, 13C, 14C and 15C are vertical cross-sectional views corresponding to FIG. 1C.

Referring to FIGS. 11A, 11B, and 11C, a lower structure LS may be formed. The lower structure LS may include the substrate 3, the circuit device TR on (in) the substrate 3, a peripheral interconnection 23 and a peripheral plug 20 electrically connected to the circuit device TR, a first peripheral insulating layer 30 on (e.g., covering, extending around, or surrounding) a side surface of a portion the peripheral plug 20 and a side surface of a portion of the circuit device TR, and a second peripheral insulating layer 32 on (e.g., covering, extending around, or surrounding) (a side surface and/or a lower surface of) the peripheral interconnection 23 and (a side surface of a portion of) the peripheral plug 20, as described with reference to FIGS. 1B and 1C.

An etch stop layer 40 may be formed on the lower structure LS. The etch stop layer 40 may be on (e.g., overlap in the Z-direction or cover) the peripheral interconnection 23 and the second peripheral insulating layer 32.

A bit line 50, a bit line plug 53, a bit line insulating layer 56, and a shielding pattern 60 may be formed on (or above) the etch stop layer 40. For example, the bit line plug 53 may be formed to extend in the bit line insulating layer 56 and pass through the etch stop layer 40 and to be in contact with the peripheral interconnection 23, and the bit line 50 may be formed on the bit line plug 53. An insulating material may be deposited to be on (e.g., to cover) the bit line plug 53 and the bit line 50, and the shielding pattern 60 may be formed on the insulating material. Subsequently, the bit line insulating layer 56 may be formed by further depositing the insulating material to be on (e.g., to cover) the shielding pattern 60. The bit lines 50 may extend in an X-direction, and may be spaced apart from each other in a Y-direction. The shielding patterns 60 may extend in the X-direction, and may be spaced apart from each other in the Y-direction. The shielding patterns 60 may be disposed alternately with the bit lines 50 in the Y-direction.

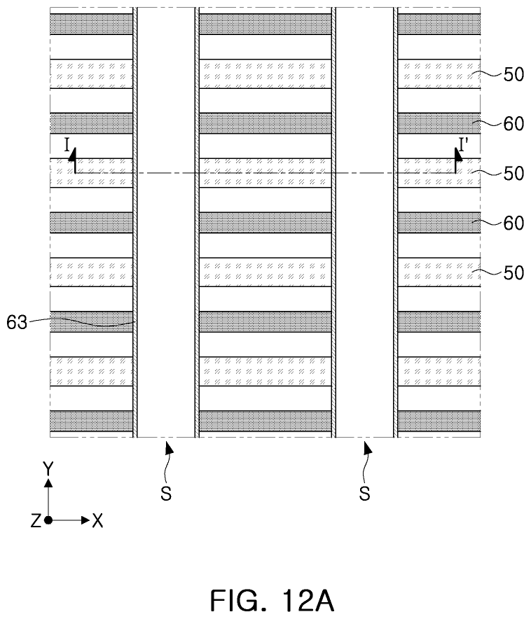

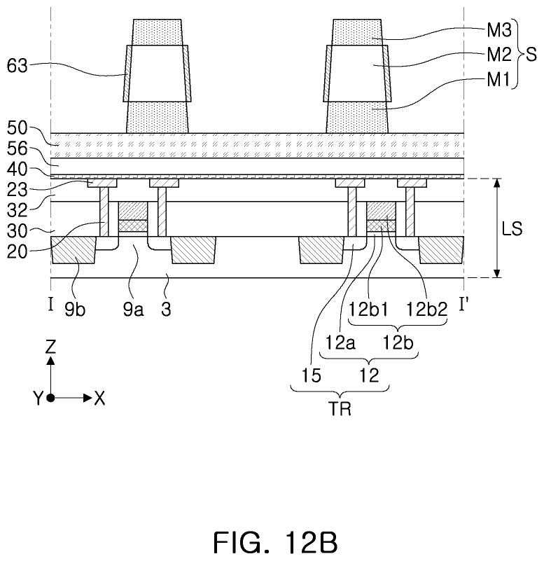

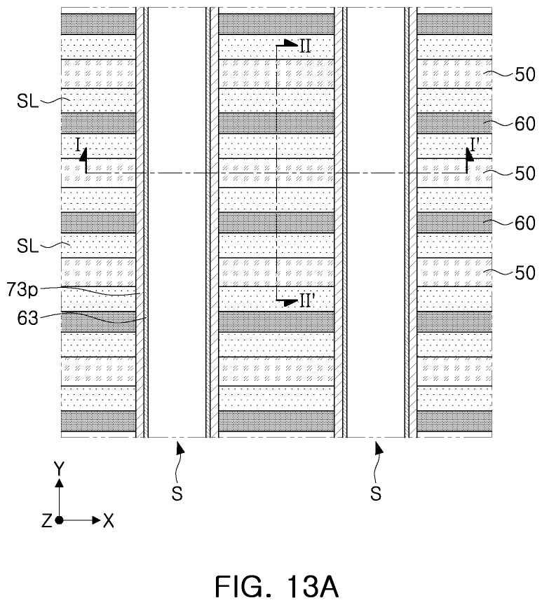

Referring to FIGS. 12A and 12B, a mold stack S may be formed on the bit line 50 and the bit line insulating layer 56. Insulating material layers may be sequentially stacked on (e.g., to cover) the bit line 50 and the bit line insulating layer 56, and may then be patterned to form the mold stack S. In an example embodiment, the mold stack S may include a first molded layer M1, a second molded layer M2, and a third molded layer M3, sequentially stacked. The mold stacks S may extend in the Y-direction, and may be spaced apart from each other in the X-direction. In an example embodiment, the mold stack S may have a tapered shape (e.g., a trapezoidal shape) in which an horizontal width of the mold stack S in the X-direction upwardly decreases, but the present inventive concept is not limited thereto.

In an example embodiment, when the insulating material layers are patterned to form the mold stack S, an upper surface of the bit line 50 may be recessed. For example, as illustrated in FIG. 7, a portion of the upper surface of the bit line 50, not covered by the mold stack S, may be recessed.

Subsequently, a metal-containing material layer may be formed on (e.g., to cover) the bit line 50, the bit line insulating layer 56, and the mold stack S, and then the metal-containing material layer may be etched to expose upper surfaces of the bit line 50, the bit line insulating layer 56, and the mold stack S, such that a metal-containing layer 63 may be formed (from the metal-containing material layer). Forming the metal-containing layer 63 may include performing a first etching process to expose an upper portion of the side surface of the mold stack S, and performing a second etching process to expose a lower portion the side surface of the mold stack S.

In the first etching process, the metal-containing material layer may be anisotropically etched to expose the upper surfaces of the bit line 50, the bit line insulating layer 56, and the mold stack S, and to expose an upper portion of the side surface of the mold stack S. The second etching process may include a wet etching process and/or a directional etching process. For example, the metal-containing material layer may be selectively etched using the wet etching process to expose a lower portion of the side surface of the mold stack S. In some embodiments, the metal-containing material layer, covering the lower portion of the side surface of the mold stack S, may be etched using the directional etching process. For example, as illustrated in FIG. 6, a portion of the upper surface of the bit line 50, adjacent to the mold stack S, may be recessed using the directional etching process.

The metal-containing layers 63 may be disposed on opposite side surfaces of the mold stack S (in the X-direction). For example, the metal-containing layers 63 may extend in the Y-direction along the mold stack S. The lower and upper portions of the side surfaces of the mold stack S may not be covered by the metal-containing layer 63. For example, the metal-containing layer 63 may be on (e.g., may cover) a side surface of the second molded layer M2 of the mold stack S, but may not be on (e.g., may not cover) side surfaces of the first molded layer M1 and the third molded layer M3. In some example embodiments, the metal-containing layer 63 may be partially on (e.g., may partially cover) the side surfaces of the first molded layer M1 and the third molded layer M3.

In an example embodiment, the metal-containing layer 63 may be disposed in the mold stack S. For example, as illustrated in FIGS. 10A to 10C, the metal-containing layer 63 may be in (e.g., inserted into) the second molded layer M2. In some embodiments, the metal-containing layer 63 may be disposed between the first molded layer M1 and the third molded layer M3 in the Z-direction. For example, in a cross-sectional view, the second molded layer M2 may include portions spaced apart from each other in the Z-direction by the metal-containing layer 63.

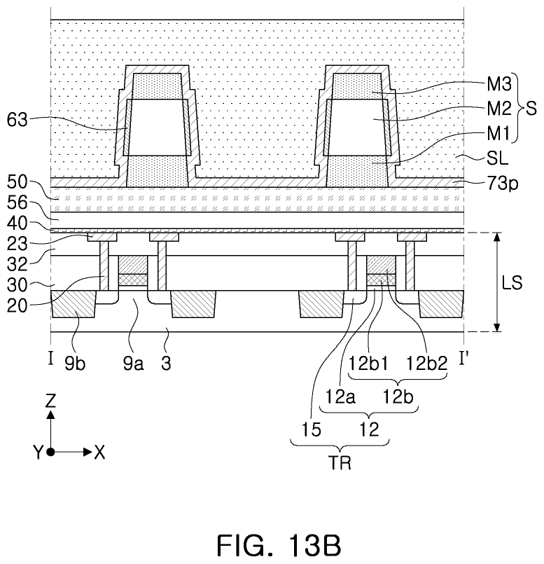

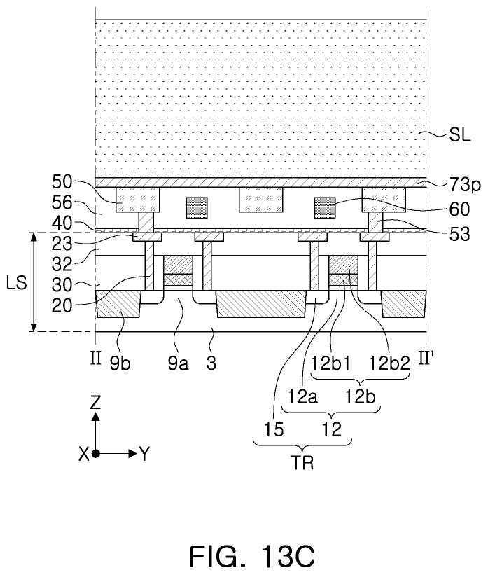

Referring to FIGS. 13A, 13B, and 13C, a channel material layer 73p and a sacrificial layer SL may be formed. The channel material layer 73p may be formed on (e.g., to cover) the bit line 50, the bit line insulating layer 56, the mold stack S, and the metal-containing layer 63. The sacrificial layer SL may be formed on (e.g., to cover) the channel material layer 73p. In some embodiments, the channel material layer 73p may partially cover the side surface of the mold stack S. For example, a portion of the side surface of the mold stack S may not be in contact with the channel material layer 73p.

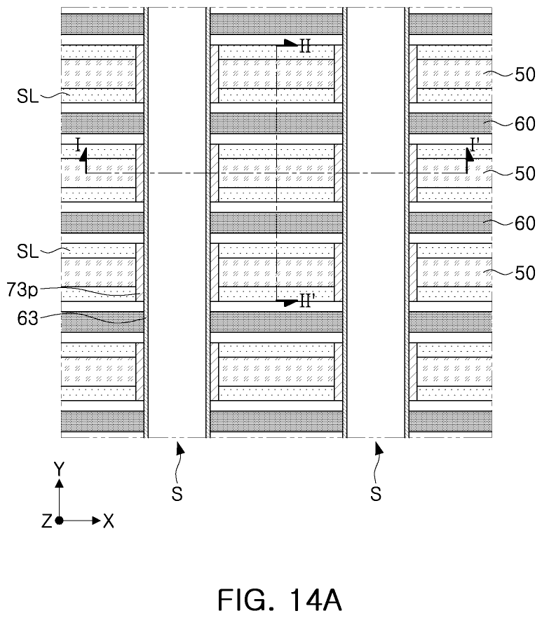

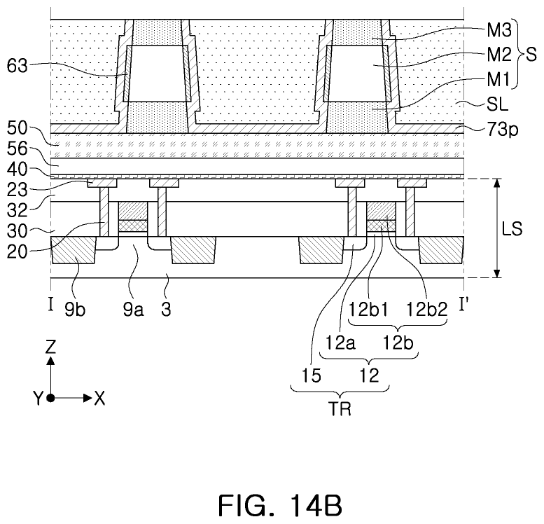

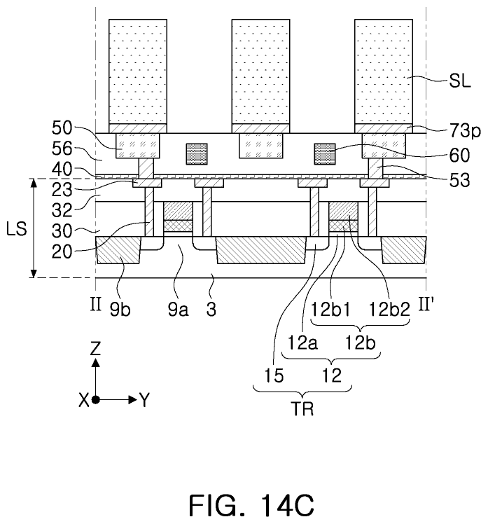

Referring to FIGS. 14A, 14B, and 14C, the channel material layer 73p and the sacrificial layer SL may be planarized and patterned. The channel material layer 73p and the sacrificial layer SL may be planarized such that an upper surface of the mold stack S (e.g., an upper surface of the third molded layer M3) is exposed, and an upper surface of the channel material layer 73p and an upper surface of the sacrificial layer SL may be coplanar with the upper surface of the mold stack S (e.g., the upper surface of the third molded layer M3).

In addition, the channel material layer 73p and the sacrificial layer SL may be patterned using an anisotropic etching process, and the upper surface of the bit line insulating layer 56 may be partially exposed. In an example embodiment, the metal-containing layer 63 may not be patterned. For example, in plan view, the metal-containing layer 63 may be disposed on the side surface of the mold stack S, and may extend in the Y-direction. The channel material layers 73p may be on (e.g., in contact with) side surfaces of the metal-containing layers 63, and may be spaced apart from each other in the X-direction and the Y-direction.

In an example embodiment, before a process of forming the channel material layer 73p, described with reference to FIGS. 13A and 13B, is performed, the metal-containing layer 63 may be patterned. Subsequently, the channel material layer 73p may be formed and patterned. For example, as illustrated in FIGS. 8 and 9, the metal-containing layers 63 may be disposed to be spaced apart from each other (in the Y-direction) along the side surface of the mold stack S.

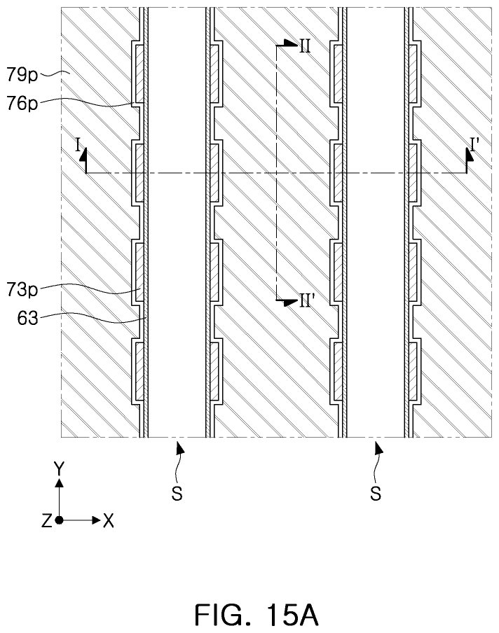

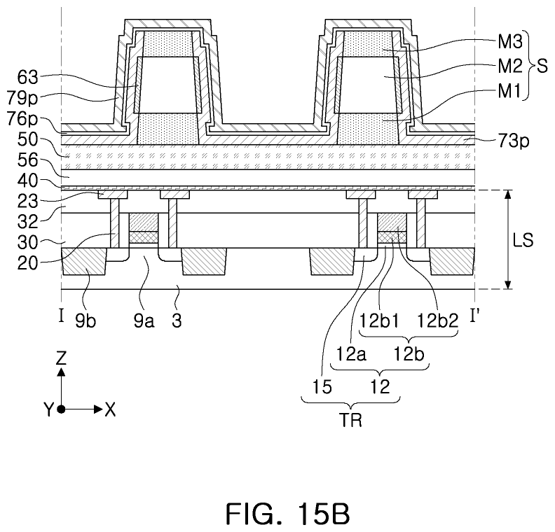

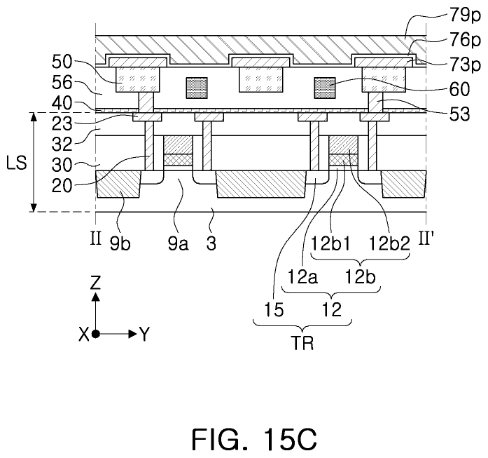

Referring to FIGS. 15A, 15B, and 15C, the sacrificial layer SL may be removed, and a dielectric material layer 76p and a conductive layer 79p may be formed. The dielectric material layer 76p may be conformally formed on (along) the bit line insulating layer 56, the channel material layer 73p, and the mold stack S. The conductive layer 79p may be on (e.g., may cover) the dielectric material layer 76p.

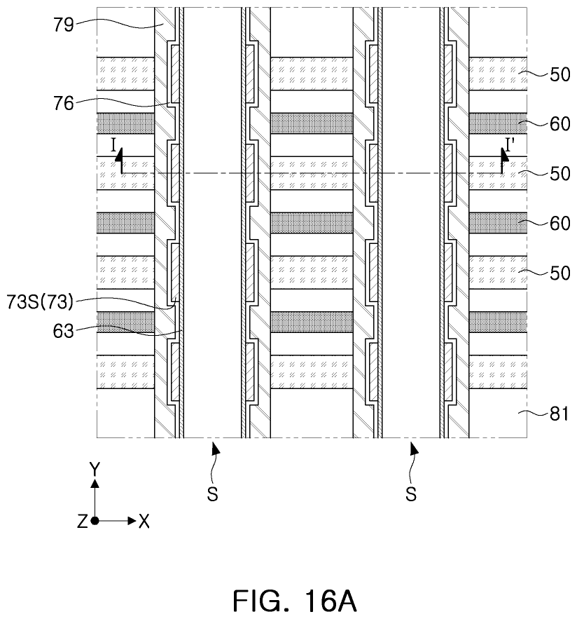

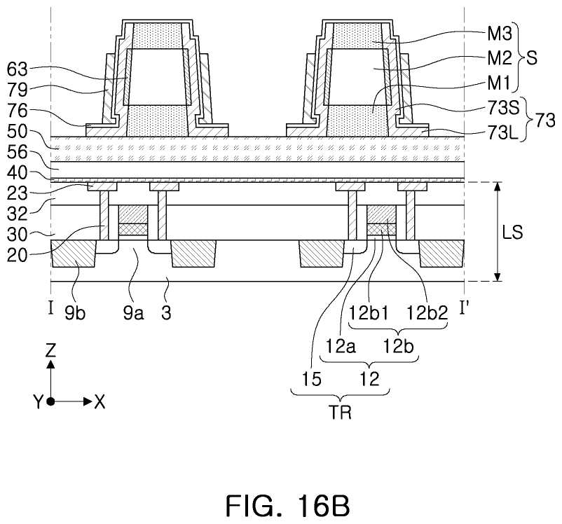

Referring to FIGS. 16A and 16B, the dielectric material layer 76p and the conductive layer 79p may be etched using an anisotropic etching process to form the dielectric structure 76 and the word line 79, respectively. In an example embodiment, a portion of the dielectric structure 76, covering the upper surface of the mold stack S, may remain without being removed, but the present inventive concept is not limited thereto. In some example embodiments, a portion of the dielectric structure 76, covering the upper surface of the mold stack S, may be removed, and the upper surface of the mold stack S may be exposed.

In plan view, the word lines 79 may intersect (e.g., overlap in the Z-direction) the bit lines 50. For example, the word lines 79 may be disposed on the side surface of the mold stack S, extend in the Y-direction, and be spaced apart from each other in the X-direction.

In an example embodiment, the channel structure 73 may be formed by etching a portion of the channel material layer 73p between the mold stacks S. The channel structure 73 may have a horizontal portion 73L on (e.g., in contact with) the bit line 50, the horizontal portion 73L extending in a horizontal direction, and a vertical channel portion 73S extending upwardly from one end of the horizontal portion 73L. For example, the vertical channel portion 73S may be on or above the horizontal portion 73L. The vertical channel portion 73S may overlap the horizontal portion 73L in the Z-direction. The vertical channel portion 73S may extend away from the bit line 50. In some embodiments, the vertical channel portion 73S and the horizontal portion 73L may form an integrated unitary structure (e.g., the channel structure 73). A portion of the channel material layer 73p may be etched to partially expose the upper surface of the bit line 50 between the mold stacks S. In some example embodiments, the channel material layer 73p may extend, without being disconnected, between mold stacks S adjacent to each other in the X-direction. For example, the channel material layer 73p may cover side surfaces of a plurality of mold stacks S, and the upper surface of the bit line 50 may not be exposed unlike the illustration in FIG. 16B.

Referring back to FIGS. 1A, 1B, 1C, 2, and 3, an interlayer insulating layer 81 and an upper capping layer 82 may be formed. The interlayer insulating layer 81 may be formed on (e.g., to cover) the bit line 50, the bit line insulating layer 56, the channel structure 73, the dielectric structure 76, and the word line 79. The interlayer insulating layers 81 may extend in the Y-direction, and may be spaced apart from each other in the X-direction. The interlayer insulating layers 81 may be disposed alternately with the molded structures MS in the X-direction. The upper capping layer 82 may be on (e.g., cover) an upper surface of the interlayer insulating layer 81.

A landing pad 83 and an insulating pattern 86 may be formed on the upper capping layer 82. The landing pad 83 may be formed by patterning the upper capping layer 82 to expose the channel structure 73, partially etching the exposed channel structure 73, and filling the partially etched channel structure 73 with a conductive material. The landing pad 83 may be electrically connected to the bit line 50 through the channel structure 73. The insulating patterns 86 may be formed between the landing pads 83.

An information storage structure 87 may be formed on the landing pad 83 and the insulating pattern 86 to manufacture a semiconductor device 100. As described with reference to FIGS. 1A, 1B, and 1C, the information storage structure 87 may include first electrodes 88a electrically connected to the landing pads 83, the first electrodes 88a in contact with the landing pads 83, a second electrode 88c on the first electrodes 88a, and a dielectric layer 88b between the first electrodes 88a and the second electrode 88c.

In an example embodiment, an annealing process may be performed before the landing pad 83 and the insulating pattern 86 are formed and the information storage structure 87 is formed. An oxide layer 66 may be formed between the metal-containing layer 63 and the vertical channel portion 73S of the channel structure 73 using the annealing process. In the annealing process, the metal-containing layer 63 may scavenge oxygen from the channel structure 73, and the scavenged oxygen may react (e.g., chemically combined) with the metal-containing layer 63 to form the oxide layer 66. A metal element of the metal-containing layer 63 may react (e.g., may be chemically combined) with an oxygen element of the channel structure 73 to form the oxide layer 66. For example, when the channel structure 73 includes a metal semiconductor oxide material, such as IGZO, weakly-bonded oxygen may be scavenged from metal-oxide bonds of the metal semiconductor oxide material using the annealing process, thereby reducing defects in the metal semiconductor oxide material, and improving mobility of the channel structure 73. Accordingly, the semiconductor device 100 may have improved electrical properties. In an example embodiment, the annealing process may be performed after the information storage structure 87 is formed.

According to example embodiments of the present inventive concept, a metal-containing layer may scavenge weakly-bonded oxygen from a channel structure, thereby improving mobility of the channel structure. Accordingly, a semiconductor device may have improved electrical properties.

While example embodiments have been shown and described above, it will be apparent to those skilled in the art that modifications and variations could be made without departing from the scope of the present inventive concept as defined by the appended claims.

What is claimed is:

1. A semiconductor device comprising:
a bit line;
a molded structure on the bit line, the molded structure including a metal-containing layer;
a channel structure on a side surface of the molded structure, the channel structure having a horizontal portion on the bit line and a vertical channel portion extending upwardly from one end of the horizontal portion, the vertical channel portion having at least a portion on a side surface of the metal-containing layer;
a word line on the horizontal portion, the word line overlapping the bit line in a first direction; and
a landing pad on the vertical channel portion, the landing pad electrically connected to the channel structure,
wherein the molded structure further includes a first oxide layer between the metal-containing layer and the vertical channel portion in a second direction,
wherein the vertical channel portion includes:
an upper portion in contact with the landing pad;
a lower portion connected to the horizontal portion; and
an intermediate portion between the upper portion and the lower portion in the first direction, the intermediate portion in contact with the first oxide layer,
wherein the first direction is perpendicular to an upper surface of the bit line, and
wherein the second direction is parallel with the upper surface of the bit line.

2. The semiconductor device of claim 1, wherein the intermediate portion of the vertical channel portion overlaps the metal-containing layer and the first oxide layer in the second direction.

3. The semiconductor device of claim 1, wherein the intermediate portion of the vertical channel portion protrudes in the second direction from the upper portion and the lower portion of the vertical channel portion.

4. The semiconductor device of claim 1, wherein the molded structure further includes a mold stack on the bit line, and
wherein the upper portion and the lower portion of the vertical channel portion are in contact with the mold stack.

5. The semiconductor device of claim 4, wherein the metal-containing layer is on a side surface of the mold stack.

6. The semiconductor device of claim 5, wherein the metal-containing layer includes a first side surface facing the intermediate portion of the vertical channel portion in the second direction, and a second side surface opposite to the first side surface in the second direction, the second side surface in contact with the side surface of the mold stack.

7. The semiconductor device of claim 5, wherein an upper surface of the metal-containing layer is convex.

8. The semiconductor device of claim 5, wherein a lower surface of the metal-containing layer is convex.

9. The semiconductor device of claim 5, wherein a lower surface of the metal-containing layer is concave.

10. The semiconductor device of claim 5, wherein an upper surface of the bit line includes a recess, adjacent to the mold stack, and
wherein the horizontal portion is in at least a portion of the recess.

11. The semiconductor device of claim 5, wherein an upper surface of the bit line includes a recess, and
wherein the horizontal portion longitudinally extends in at least a portion of the recess in the second direction.

12. The semiconductor device of claim 4, wherein the molded structure further includes a second oxide layer,
wherein the metal-containing layer is in the mold stack, and
wherein the first oxide layer and the second oxide layer face each other in the second direction with the metal-containing layer interposed therebetween.

13. The semiconductor device of claim 1, wherein the metal-containing layer includes a first metal element,
wherein the channel structure includes a semiconductor oxide including oxygen, and
wherein the first oxide layer includes the first metal element and the oxygen from the semiconductor oxide of the channel structure.

14. A semiconductor device comprising:
bit lines extending in a first horizontal direction, the bit lines spaced apart from each other in a second horizontal direction that intersects the first horizontal direction;
a molded structure extending on the bit lines in the second horizontal direction;
a first channel structure and a second channel structure on a side surface of the molded structure, the first channel structure and the second channel structure spaced apart from each other in the second horizontal direction, the first channel structure and the second channel structure respectively having a horizontal portion on the bit lines and a vertical channel portion extending away from the bit lines;
a word line on the horizontal portions, the word line extending in the second horizontal direction;
a dielectric structure extending between the word line and the first channel structure and between the word line and the second channel structure; and
landing pads on the vertical channel portions,
wherein the molded structure includes a first metal-containing layer overlapping the first channel structure in the first horizontal direction, and a first oxide layer between the first metal-containing layer and the first channel structure, and
wherein the first horizontal direction and the second horizontal direction are parallel with an upper surface of the bit lines.

15. The semiconductor device of claim 14, wherein the first metal-containing layer extends in the second horizontal direction,
wherein the molded structure further includes a second oxide layer between the first metal-containing layer and the second channel structure.

16. The semiconductor device of claim 15, wherein
the molded structure further includes a mold stack on the bit lines,
wherein the first metal-containing layer is in the mold stack, and
wherein the first oxide layer is coplanar with a side surface of the mold stack.

17. The semiconductor device of claim 14, wherein the molded structure further includes a second metal-containing layer overlapping the second channel structure in the first horizontal direction, and a second oxide layer between the second metal-containing layer and the second channel structure.

18. The semiconductor device of claim 17, wherein a portion of the dielectric structure is in contact with the first metal-containing layer and the second metal-containing layer, and overlaps the first metal-containing layer and the second metal-containing layer in the second horizontal direction.

19. The semiconductor device of claim 17, wherein a horizontal width of the first channel structure in the second horizontal direction is wider than a horizontal width of the first metal-containing layer in the second horizontal direction, and
wherein a portion of the first channel structure overlaps the first metal-containing layer in the second horizontal direction.

20. A semiconductor device comprising:
a lower structure including a circuit device;
a bit line on the lower structure;
a molded structure on the bit line, the molded structure including a metal-containing layer;
a channel structure on a side surface of the molded structure, the channel structure having a horizontal portion on the bit line and a vertical channel portion extending away from the bit line, the vertical channel portion having at least a portion on a side surface of the metal-containing layer;
a word line on the horizontal portion, the word line overlapping the bit line in a first direction that is perpendicular to an upper surface of the bit line;
an interlayer insulating layer on the bit line and the word line;
an upper capping layer on the molded structure and the interlayer insulating layer;
a landing pad on the vertical channel portion, the landing pad passing through the upper capping layer in the first direction, the landing pad electrically connected to the channel structure; and
an information storage structure on the landing pad,
wherein the molded structure includes an oxide layer between the metal-containing layer and the vertical channel portion,
wherein the vertical channel portion includes:
an upper portion in contact with the landing pad;
a lower portion connected to the horizontal portion; and
an intermediate portion between the upper portion and the lower portion in the first direction, the intermediate portion in contact with the oxide layer,
wherein the metal-containing layer includes a first metal element,
wherein the channel structure includes a semiconductor oxide including oxygen, and
wherein the oxide layer includes the first metal element and the oxygen from the semiconductor oxide of the channel structure.
